(19) United States
(12) Patent Application Publication
(10) Pub. No.: US 2010/0046290 A1
(43) Pub. Date: Feb. 25, 2010

(54) FLASH MEMORY DEVICE AND MEMORY SYSTEM

(75) Inventors: Ki-Tae PARK, Seongnam-si (KR); Myoung Gon KANG, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/509,611

(22) Filed: Jul. 27, 2009

(30) Foreign Application Priority Data
Aug. 21, 2008 (KR) 10-2008-81960

(51) Int. Cl. G11C 16/06; G11C 16/04

(52) U.S. Cl. 365/185.2; 365/185.18

(57) ABSTRACT

A flash memory device includes a first switch connecting one of a first cell string and a second cell string to a first bit line selectively, a second switch connecting the second cell string to a second bit line, and a control logic circuit providing bias voltages to the first and second cell strings through the first and second bit lines respectively and controlling the first and second cell stings to be simultaneously programmed.

### CROSS-REFERENCE TO RELATED APPLICATIONS

This U.S. non-provisional patent application claims priority under 35 U.S.C. §119 to Korean Patent Application No. 10-2008-81960 filed on Aug. 21, 2008, the subject matter of which is hereby incorporated by reference.

### BACKGROUND

The present invention relates to semiconductor memory devices. More particularly, the invention relates to flash memory devices and a memory system incorporating same.

Semiconductor memory devices store data and allow stored data to be retrieved by external circuits. Semiconductor memory devices may be generally classified as volatile and nonvolatile.

Volatile memory provides high speed data access (i.e., read/write operations), but loses stored data in the absence of applied power. Volatile memory includes static random access memories (SRAMs), dynamic RAMs, and synchronous RAMs (SRAMs).

In contrast, nonvolatile memory retains stored data in the absence of applied power. There are many kinds of nonvolatile memory, including; mask read-only memory (MROM), programmable ROM (PROM), erasable and programmable ROM (EPROM), electrically erasable and programmable ROM (EEPROM), flash memory, phase-change memory (PRAM), magneto-resistance RAM (MRAM), resistive RAM (RRAM), ferroelectric RAM (FRAM), and so forth.

The data stored in a conventional flash memory device is organized in a memory cell array allowing data access to so-designated odd and even pages. Cell strings corresponding to each even page are connected to even bit lines, while cell strings corresponding to each odd page are connected to odd bit lines. A unit page buffer is shared between a pair of even and odd bit lines. During a programming operation, the page buffer applies a bias voltage to one of the even and odd bit lines. In this manner, a programming operation programs one or more cell strings connected to an even or odd bit line.

The rate at which programming operations may be executed within a flash memory is an important performance criteria. Conventional flash memory devices typically execute a unit page based programming operation in about 200 μs. Thus, assuming the foregoing even/odd page arrangement, it will take about 400 μs to sequentially program the even and odd pages of the unit page.

### SUMMARY

Embodiments of the invention are directed to flash memory devices capable of simultaneously programming all of the cell strings in a unit page. Embodiments of the invention are also directed to flash memory devices capable of reducing or preventing charge leakage during programming operations.

In one aspect of the invention, a flash memory device comprises; a first switch configured to selectively connect one of a first cell string and a second cell string to a first bit line, a second switch configured to connect the second cell string to a second bit line, and a control logic circuit configured to respectively provide bias voltages to the first and second cell strings through the first and second bit lines to enable simultaneously programming of the first and second cell stings.

In another aspect of the invention, a flash memory device comprises; a plurality of cell strings connected between first and second switches, first bit lines connected to one of the 2n'th and 2n−1'th cell strings, where “n” is a positive integer among the plurality of cell strings through the first switch, second bit lines connected to one of the 2n'th and 2n+1'th cell strings among the plurality of cell strings through the second switch, and a control logic circuit configured to selectively connected the 2n'th and 2n−1'th cell strings to one of the first bit lines or one of the second bit lines, such that plurality of cell strings are simultaneously programmed by providing bias voltages through the first and second bit lines.

In another aspect of the invention, a memory system comprises; a flash memory device and a controller configured to control the flash memory device. The flash memory device comprises; a first switch connecting a first cell string to a first bit line, a second switch connecting a second cell string to a second bit line, and a control logic circuit respectively providing bias voltages to the first and second cell strings through the first and second bit lines, and controlling the first and second cell strings to be programmed simultaneously.

### BRIEF DESCRIPTION OF THE FIGURES

Non-limiting and non-exhaustive embodiments of the present invention will be described with reference to the following figures. In the figures:

FIG. 1 is a general block diagram of a memory system according to an embodiment of the invention;

FIG. 2 is a block and circuit diagram illustrating a memory cell array for a flash memory device according to an embodiment of the invention;

FIG. 3 is a table listing bias voltage conditions for operations executed in the flash memory device of FIG. 2;

FIG. 4 is a circuit diagram showing another embodiment of a memory cell array for a flash memory device according to an embodiment of the invention;

FIG. 5 is a table listing bias voltage conditions for operations executed in the flash memory device of FIG. 4;

FIG. 6 is a circuit diagram showing yet another embodiment of a memory cell array for a flash memory device according to an embodiment of the invention;

FIG. 7 is a table listing bias voltage conditions for operations executed in the flash memory device of FIG. 6;

FIG. 8 is a flow chart summarizing a programming method for a flash memory device, such as the ones illustrated in FIGS. 2-7 in accordance with an embodiment of the invention;

FIG. 9 is a circuit diagram showing yet another embodiment of a memory cell array for a flash memory device according to an embodiment of the invention;

FIG. 10 is a circuit diagram showing yet another embodiment of a memory cell array for a flash memory device according to an embodiment of the invention; and

FIG. 11 is a general block diagram of a computing system incorporating the memory system of FIG. 1.

### DESCRIPTION OF EMBODIMENTS

Embodiments of the invention will now be described in some additional detail with reference to the accompanying drawings.

The present invention may, however, be embodied in different forms and should not be constructed as being limited to only the illustrated embodiments. Rather, these embodiments are presented as teaching examples. Throughout the written description and accompanying figures, like reference numbers and symbols refer to like or similar elements.

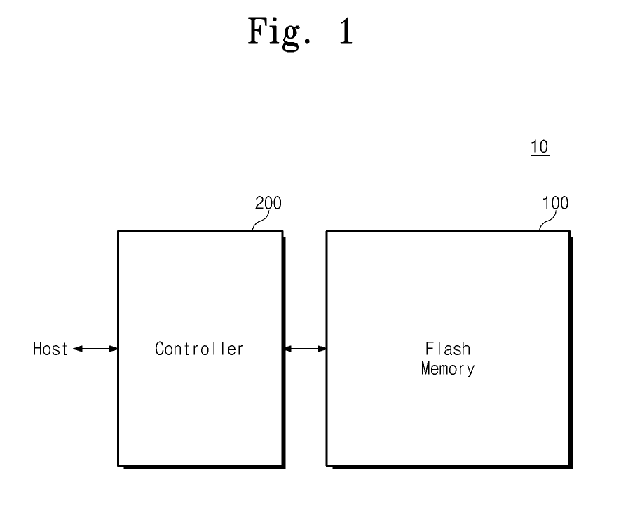

Figure (FIG.) 1 is a block diagram of a memory system 10 according to an embodiment of the invention. Referring to FIG. 1, the memory system 10 generally comprises a flash memory device 100 and a controller 200.

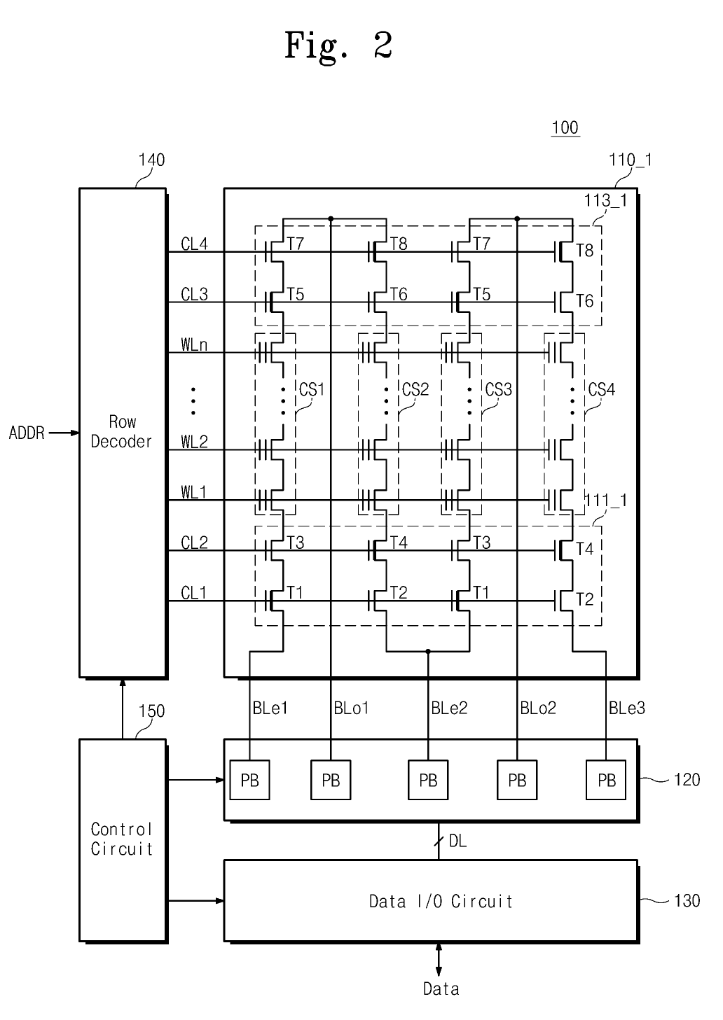

As will be further explained hereafter with reference to FIGS. 2-10, the flash memory device 100 comprises; a first switch configured to electrically connect a first cell string to a first bit line, a second switch configured to electrically connect a second cell string to a second bit line, and a control logic circuit configured to provide bias voltages to the first and second cell strings via connected first and second bit lines, respectively. The control logic circuit is also configured to enable the simultaneous programming of the first and second cell stings.

The controller 200, as is typical, is interposed between a host device and the flash memory device 100. The controller 200 essentially controls the transfer of data between the host device and the flash memory device 100. The controller 200 may be of conventional design and operation, and may include well-known components such as a RAM, a processing unit, a host interface, and a memory interface.

The RAM is used as an operating memory by the processing unit. The processing unit functions to control the overall operation of the controller 200. The host interface enables one or more data communication protocol(s) by which data is transferred between the host device and the controller 200.

Depending on the type of controller used as the controller 200, it may be configured to communicate with the host device via one of many available protocols, such as those associated with a universal serial bus (USB), multimedia card (MMC) interface, peripheral component interconnection—express (PCI-E) interface, serial advanced technology attachment (SATA), parallel advanced technology attachment (PATA), small computer system interface (SCSI) interface, enhanced small disk interface (SDI), integrated drive electronics (IDE), and so forth.

The memory interface of the controller 200 may also be conventional in nature and facilitates the transfer of data between the controller 20 and the flash memory device 100. In certain embodiments of the invention, the controller 200 may include certain conventionally understood error detection and/or correction (ECC) capabilities operative on the data being stored and retrieved from the flash memory device 100.

In certain embodiments of the invention, the controller 200 and flash memory device 100 may be integrated (i.e., commonly fabricated) into a single integrated circuit (IC) package. For example, the controller 200 and flash memory device 100 may be integrated into (or mounted onto) one or more of the IC packages commonly recognized as a memory card, a personal computer (PC) memory card international association (PCMCIA) card, a compact flash (CF) card, a smart media card (SM/SMC), a memory stick, a multimedia card (MMC, RS-MMC, or MMCmicro), a secret digital card (SD, miniSD, or microSD), a universal flash storage (UFS), etc.

The controller 200 and flash memory device 100 may alternately be integrated into a solid state drive/disk (SSD). If the memory system 10 is used as an SSD, it remarkably improves an operation rate of the host coupled to the memory system 10.

FIG. 2 is a block and circuit diagram illustrating a memory cell array for the flash memory device 100 according to an embodiment of the invention. Referring to FIG. 2, the flash memory device 100 comprises; a memory cell array 110_1, a page buffer circuit 120, a data input/output circuit 130, a row decoder 140, and a control logic circuit 150.

The memory cell array 110_1 comprises a first switch 111_1, a second switch 113_1, and cell strings CS1˜CS4 of plural memory cells serially connected with each other. The cell strings CS1˜CS4 are connected between the first and second switches 111_1 and 113_1. While FIG. 2 shows only four (4) representative cell strings CS1˜CS4, the present invention is not restricted to only this particular arrangement or number of cell strings within a constituent memory cell array. The first switch 111_1 electrically connects the cell strings CS1˜CS4 to bit lines BLe1˜BLe3. The first switch 111_1 includes a plurality of first transistors T1˜T4. Between the first cell string CS1 and the bit line BLe1 are connected the transistors T1 and T3. Between the second cell string CS2 and the bit line BLe2 are connected the transistors T2 and T4. Between the third cell string CS3 and the bit line BLe2 are connected the transistors T1 and T3. Between the fourth cell string CS4 and the bit line BLe3 are connected the transistors T2 and T4. In the illustrated embodiment, first transistors T1 and T4 are assumed to be depletion type transistors, but other types of transistors might be used.

The second switch 113_1 electrically connects the cell strings CS1˜CS4 to bit lines BLo1 and BLo2. The second switch 113_1 includes a plurality of second transistors T5˜T8. Between the first cell string CS1 and the bit line BLo1 are connected the transistors T5 and T7. Between the second cell string CS2 and the bit line BLo1 are connected the transistors T6 and T8. Between the third cell string CS3 and the bit line BLo2 are connected the transistors T5 and T7. Between the fourth cell string CS4 and the bit line BLo2 are connected the transistors T6 and T8. Here, the transistors T5 and T8 are depletion types. The bit lines, BLe1˜BLe3, and BLo1 and BLo2, are connected to the page buffer circuit 120. Control gates for the memory cells included in the cell strings CS1˜CS4 are coupled to the row decoder 140 through word lines WL1˜WLn. The gates of the transistors T1 and T2 are coupled to the row decoder 140 through a control line CL1. The gates of the transistors T3 and T4 are coupled to the row decoder 140 through a control line CL2. The gates of the transistors T5 and T6 are coupled to the row decoder 140 through a control line CL3. The gates of the transistors T7 and T8 are coupled to the row decoder 140 through a control line CL4.

The page buffer circuit 120 is connected between the memory cell array 110_1 and the data input/output circuit 130. The page buffer circuit 120 operates in response to control by the control logic circuit 150.

The page buffer circuit 120 applies bias voltages to the bit lines BLe1˜BLe3, and BLo1 and BLo2. For instance, during a programming operation, the page buffer circuit 120 applies the power source voltage Vcc and the ground voltage Vss to the bit lines BLe1˜BLe3, and BLo1 and BLo2. During a read operation, the page buffer circuit 120 applies the power source voltage Vcc and the ground voltage Vss to the bit lines BLe1˜BLe3, and BLo1 and BLo2.

The page buffer circuit 120 receives and stores “write data” to be written to the memory cell array 110_1, from the data input/output circuit 130, and applies bias voltages to the bit lines BLe1˜BLe3, and BLo1 and BLo2. The page buffer circuit 120 stores “read data” read from the memory cell array 110_1, and transfers the read data to the data input/output circuit 130.

The page buffer circuit 120 is organized around a plurality of page buffers PB respectively connected to the bit lines BLe1˜BLe3, and BLo1 and BLo2. As is conventionally understood, each page buffer may include one or more data latches. The data latches of the page buffers PB store write/read data to be transferred from/to the data input/output circuit 130 in response to bias voltages applied to the bit lines, BLe1˜BLe3 and BLo1 and BLo2.

The data input/output circuit 130 exchanges “data” between the page buffers PB via a data line DL, and also exchanges data with an external device. For instance, the data input/output circuit 130 may exchange data with the controller 200 shown in FIG. 1. The data input/output circuit 130 operates under the control of the control logic circuit 150. The data input/output circuit 130 may be conventional in its design and may include well-known components such as column pass gates and data buffers.

The row decoder 140 is connected to the memory cell array 110_1. The row decoder 140 operates under the control of the control logic circuit 150. According to an address signal ADDR received from an external circuit, the row decoder 140 selects between the word lines WL1˜WLn and control lines CL1˜CL4. For example, the row decoder 140 may receive an address signal ADDR from the controller 200 shown in FIG. 1.

As is conventionally understood, the control logic circuit 150 is configured to control the overall operations of the flash memory device 100.

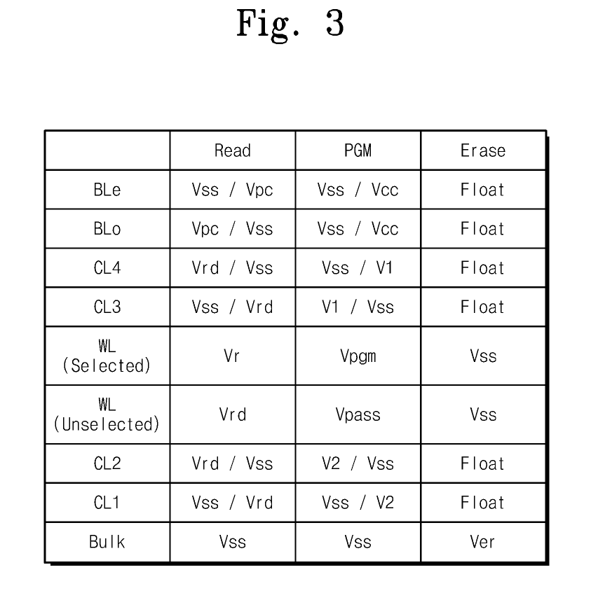

FIG. 3 is a table listing voltage conditions for certain operations of executed by flash memory device 100 of FIG. 2. Hereinafter, a read operation executed by the flash memory device 100 according to an embodiment of the invention will be described with reference to FIGS. 2 and 3.

During the read operation, page buffer circuit 120 applies ground voltage Vss or a precharging voltage Vpc to the bit lines BLe1˜BLe3, and BLo1 and BLo2. If the ground voltage Vss is applied to the bit lines BLe1˜BLe3, the bit lines BLo1 and BLo2 are supplied with the precharging voltage Vpc. To the contrary, if the precharging voltage Vpc is applied to the bit lines BLe1˜BLe3, the bit lines BLo1 and BLo2 are supplied with the ground voltage Vss. In certain embodiments of the invention, the precharging voltage Vpc may be equal to the power source voltage Vcc.

A first read voltage Vrd or the ground voltage Vss is applied to the control lines CL1˜CL4. If the first read voltage Vrd is applied to the control lines CL1 and CL3, the ground voltage Vss is applied to the control lines CL2 and CL4. To the contrary, if the ground voltage Vss is applied to the control lines CL1 and CL3, the first read voltage Vrd is applied to the control lines CL2 and CL4. Under this set of conditions, the first read voltage Vrd is set to have a level sufficient to turn ON the transistors T2, T3, T6, and T7 to normally execute the read operation. For instance, the read voltage Vrd may be a positive voltage of predetermined level.

Referring to the first and second switches 111_1 and 113_1, a single control line (e.g., CL1) is connected to the transistor T2 and the depletion transistor T1. If the ground voltage Vss is applied to the control line CL1, the depletion transistor T1 is turned ON and the transistor T2 is turned OFF. If the first read voltage Vrd is applied to the control line CL1, the depletion transistor T1 is turned ON along with the transistor T2. In other words, the depletion transistor T1 acts as a short circuit and the transistor T2 selectively operates as a short or open switch circuit in accordance with a voltage level applied to the control line CL1.

For convenience and simplicity of description, it is assumed for the following description that ground voltage Vss is applied to the bit lines BLe1˜BLe3, the precharging voltage Vpc is applied to the bit lines BLo1 and BLo2, ground voltage Vss is applied to the control lines CL1 and CL3, and the first read voltage Vrd is applied to the control lines CL2 and CL4.

Thus, as the transistor T2 is turned OFF when the ground voltage Vss is applied to the control line CL1, the cell strings CS2 and CS4 are electrically isolated from the bit lines BLe2 and BLe3. As the transistor T3 is turned ON when the first read voltage Vrd is applied to the control line CL2, the cell strings CS1 and CS3 are electrically connected to the bit lines BLe1 and BLe2 through the first switch 111_1.

As the transistor T6 is turned OFF when the ground voltage Vss is applied to the control line CL3, the cell strings CS2 and CS4 are electrically isolated from the bit lines BLo1 and BLo2. As the transistor T7 is turned ON when the first read voltage Vrd is applied to the control line CL4, the cell strings CS1 and CS3 are electrically connected to the bit lines BLo1 and BLo2 through the second switch 113_1.

The precharging voltage Vpc is applied to the bit lines BLo1 and BLo2. Thus, the precharging voltage Vpc is applied to the cell strings CS1 and CS3 from the bit lines BLo1 and BLo2 through the second switch 113_1 when the first and second read voltages Vrd and Vr are supplied each to selected and unselected word lines. In the meantime, being applied to the bit lines BLe1˜BLe3, the ground voltage Vss is transferred to the cell strings CS1 and CS3 through the first switch 111_1. Under these conditions, the precharging voltage Vpc is developed in accordance with a logical state of a memory cell (MC) coupled to the selected word line. That is, it reads a logical state from the memory cell coupled to the selected word line. In the illustrated embodiment, the second read voltage Vr may have a voltage level between logical states of the memory cells.

A read operation directed to the cell strings CS2 and CS4 may be executed under a voltage condition different from that of a read operation directed to the cell strings CS1 and CS3. In a read operation directed to the cell strings CS2 and CS4, the precharging voltage Vpc is applied to the bit lines BLe1˜BLe3 while ground voltage Vss is applied to the bit lines BLo1 and BLo2. The first read voltage Vrd is applied to the control lines CL1 and CL2 while the ground voltage Vss is applied to the control lines CL2 and CL4.

Under these conditions, the cell strings CS2 and CS4 are electrically connected to the bit lines BLe2 and BLe3 through the first switch 111_1 and electrically connected to the bit lines BLo1 and BLo2 through the second switch 113_1. Thus, to the cell strings CS2 and CS4, the precharging voltage Vpc is provided through the first switch 111_1 and ground voltage Vss is provided through the second switch 113_1. If the first and second read voltages Vrd and Vr are applied to selected and unselected word lines, the precharging voltage Vpc is developed and logical states are read out from memory cells coupled to the selected word line.

As noted above, the flash memory device 100 according to an embodiment of the invention may be operable by alternately conducting a read operation to adjacent cell strings. In other words, the flash memory device 100 according to an embodiment of the invention may execute a read operation alternately to the 2n'th and 2n−1'th cell strings. In so doing, it reduces the effects of capacitive couplings between bit lines during the read operation, thereby enhancing voltage margins when reading the stored data values.

Hereinafter will be described a programming operation for the flash memory device 100 according to the foregoing embodiment of the invention with reference to FIGS. 2 and 3.

During the programming operation, ground voltage Vss or the power source voltage Vcc is applied to the bit lines BLe1˜BLe3 and BLo1 and BLo2. A voltage V2 or ground voltage Vss is applied to the control lines CL1 and CL2. A voltage V1 or ground voltage Vss is applied to the control lines CL3 and CL4. If ground voltage Vss is applied to the control line (e.g., CL1), the transistor T1 is turned ON while the transistor T2 is turned OFF. If the voltage V2 is applied to the control line (e.g., CL1), the transistors T1 and T2 are all turned ON. That is, the transistor T1 acts as a short circuit, while the transistor T2 acts as a switch that is turned ON or OFF by a voltage level of the control line CL1.

The voltage V1 has a level sufficient to execute the programming operation. For instance, the voltage V1 may be set to a level achieved by summing the threshold voltages of the transistors T6 and T7 to the power source voltage Vcc. The voltage V2 also has a level sufficient to execute the programming operation. For instance, the voltage V2 may be set to a level achieved by summing the threshold voltages of the transistors T2 and T3 to the power source voltage Vcc.

For convenience and simplicity of description, it is now assumed that; ground voltage Vss is applied to the bit lines BLe1˜BLe3 and BLo1 and BLo2, the ground voltage Vss is applied to the control lines CL1 and CL4, the voltage V2 is applied to the control line CL2, and the voltage V1 is applied to the control line CL3.

As the transistor T2 is turned OFF when the ground voltage Vss is applied to the control line CL1, the cell strings CS2 and CS4 are electrically isolated from the bit lines BLe2 and BLe3. As the transistor T3 is turned ON when the voltage V2 is applied to the control line CL2, the cell strings CS1 and CS3 are electrically connected to the bit lines BLe1 and BLe2 through the first switch 111_1.

As the transistor T6 is turned ON when the voltage V1 is applied to the control line CL3, the cell strings CS2 and CS4 are electrically connected to the bit lines BLo1 and BLo2 through the second switch 113_1. As the transistor T7 is turned OFF when ground voltage Vss is applied to the control line CL4, the cell strings CS1 and CS3 are electrically isolated from the bit lines BLo1 and BLo2.

Under these conditions, the cell string CS1 is electrically connected to the page buffer circuit 120 by way of the first switch 111_1 and the bit line BLe1, but electrically isolated from the second switch 113_1. The page buffer circuit 120 is biasing the bit line BLe1 with ground voltage Vss. If a program voltage is applied to a selected word line while a pass voltage Vpass is applied to unselected word lines, memory cells coupled to the selected word line of the cell string CS1 are programmed.

The cell string CS2 is electrically connected to the page buffer circuit 120 by way of the second switch 113_1 and the bit line BLo1, but electrically isolated from the first switch 111_1. The page buffer circuit 120 is biasing the bit line BLo1 on the ground voltage Vss. If a program voltage is applied to a selected word line while a pass voltage Vpass is applied to unselected word lines, memory cells coupled to the selected word line of the cell string CS2 are programmed.

The cell string CS3 is electrically connected to the page buffer circuit 120 by way of the first switch 111_1 and the bit line BLe2, but electrically isolated from the second switch 113_1. The page buffer circuit 120 is biasing the bit line BLe2 with ground voltage Vss. If a program voltage is applied to a selected word line while a pass voltage Vpass is applied to unselected word lines, memory cells coupled to the selected word line of the cell string CS3 are programmed.

The cell string CS4 is electrically connected to the page buffer circuit 120 by way of the second switch 113_1 and the bit line BLo2, but electrically isolated from the first switch 111_1. The page buffer circuit 120 is biasing the bit line BLo2 with ground voltage Vss. If a program voltage is applied to a selected word line while a pass voltage Vpass is applied to unselected word lines, memory cells coupled to the selected word line of the cell string CS4 are programmed.

In sum, the flash memory device 100 according to an embodiment of the invention is able to simultaneously program the cell strings CS1˜CS4. The control logic circuit 150 may be configured to operate general circuitry to functionally enable the simultaneous programming the cell strings CS1˜CS4.

By applying a program-inhibition voltage (e.g., the power source voltage Vcc) to a bit line corresponding to a program-inhibited cell string, the program-inhibited cell string is prevented from being programmed. For example, if the cell string CS1 is program-inhibited, the page buffer circuit 120 biases the bit line BLe1 on the program-inhibition voltage. If the cell string CS2 is program-inhibited, the page buffer circuit 120 biases the bit line BLo1 on the program-inhibition voltage. If the cell string CS3 is program-inhibited, the page buffer circuit 120 biases the bit line BLe2 on the program-inhibition voltage. If the cell string CS4 is program-inhibited, the page buffer circuit 120 biases the bit line BLo2 on the program-inhibition voltage.

The programming operation executed by the flash memory device 100 according to the foregoing embodiment of the invention may be performed using different voltage conditions. For instance, the programming operation may be executed under the following condition; ground voltage Vss is applied to the control lines CL2 and CL3, voltage V2 is applied to the control line CL1, and the voltage V1 is applied to the control line CL4.

If the voltage V2 is applied to the control line CL1, the cell strings CS2 and CS4 are electrically connected each to the bit lines BLe2 and BLe3 through the first switch 111_1. If ground voltage Vss is applied to the control line CL2, the cell strings CS1 and CS3 are electrically isolated from the first switch 111_1. If ground voltage Vss is applied to the control line CL3, the cell strings CS2 and CS4 are electrically isolated from the second switch 113_1. If the voltage V1 is applied to the control line CL4, the cell strings CS1 and CS3 are electrically connected each to the bit lines BLo1 and BLo2 through the second switch 113_1.

The cell string CS1 is electrically connected to the page buffer circuit 120 through the second switch 113_1 and the bit line BLo1, but electrically isolated from the first switch 111_1. The cell string CS1 is programmed when the page buffer circuit 120 is biasing the bit line BLo1 on ground voltage Vss.

The cell string CS2 is electrically connected to the page buffer circuit 120 through the first switch 111_1 and the bit line BLe2, but electrically isolated from the second switch 113_1. The cell string CS2 is programmed when the page buffer circuit 120 is biasing the bit line BLo1 on ground voltage Vss.

The cell string CS3 is electrically connected to the page buffer circuit 120 through the second switch 113_1 and the bit line BLo2, but electrically isolated from the first switch 111_1. The cell string CS3 is programmed when the page buffer circuit 120 is biasing the bit line BLo2 with ground voltage Vss.

The cell string CS4 is electrically connected to the page buffer circuit 120 through the first switch 111_1 and the bit line BLe3, but electrically isolated from the second switch 113_1. The cell string CS4 is programmed when the page buffer circuit 120 is biasing the bit line BLe3 with ground voltage Vss.

As such, the flash memory device 100 is able to simultaneously program the cell strings CS1˜CS4. Of further note, a program-inhibited cell string is not programmed by biasing the program-inhibition voltage on a bit line corresponding to the program-inhibited cell string.

Therefore, the flash memory device 100 according to the foregoing embodiment of the invention comprises the first switch 111_1 configured to electrically connect the first cell string CS1 to the first bit line BL01, the second switch 113_1 configured to electrically connect the second cell string CS2 to the second bit line BLe2, and the control logic circuit configured to provide bias voltages to the first and second cell strings CS1 and CS2 via the first and second bit lines BLo1 and BLe2 respectively and controlling the first and second cell stings CS1 and CS2 to be simultaneously programmed.

In other words, the flash memory device 100 according to the foregoing embodiment of the invention executes the aforementioned operations by including; the plural cell strings CS1˜CS4 connected between the first and second switches 111_1 and 113_1, first bit lines BLo1 and BLo2 electrically connected to one of the cell strings CS1˜CS4 (i.e., one of the 2n'th and 2n−1'th cell strings, where “n” is a positive integer) through the first switch 111_1, second bit lines BLe1˜BLe3 electrically connected to one of the cell strings CS1˜CS4, (i.e., one of the 2n'th and 2n+1 'th cell strings, where “n” is a positive integer) through the second switch 113_1, and a control logic circuit 150 controlling each cell string to be connected with one of the bit lines BLe1˜BLe3, and BLo1 and BLo2, and controlling the plural cell strings CS1˜CS4 to be simultaneously programmed by providing bias voltages through the bit lines electrically connected to the cell strings.

As illustrated by the foregoing, embodiments of the invention provide reduced programming time because all of the cell strings CS1˜CS 4 may be simultaneously programmed.

Hereinafter, an erase operation for the flash memory device 100 according to an embodiment of the invention will be described with reference to FIGS. 2 and 3.

The bit lines, BLe1˜BLe3, and BL01 and BLo2, are allowed to float during the erase operation. During the erase operation, the control lines CL1˜CL4 are also allowed to float. Ground voltage Vss is applied to the word lines WL1˜WLn and an erase voltage Ver is applied to the bulk of the semiconductor substrate containing the memory cells. Under these conditions, electrical charge accumulated/captured in charge storage layers of the memory cells is released via the conventionally understood mechanism referred to as Fowler-Nordheim (F-N) tunneling. In this manner, the memory cells (MC) are erased.

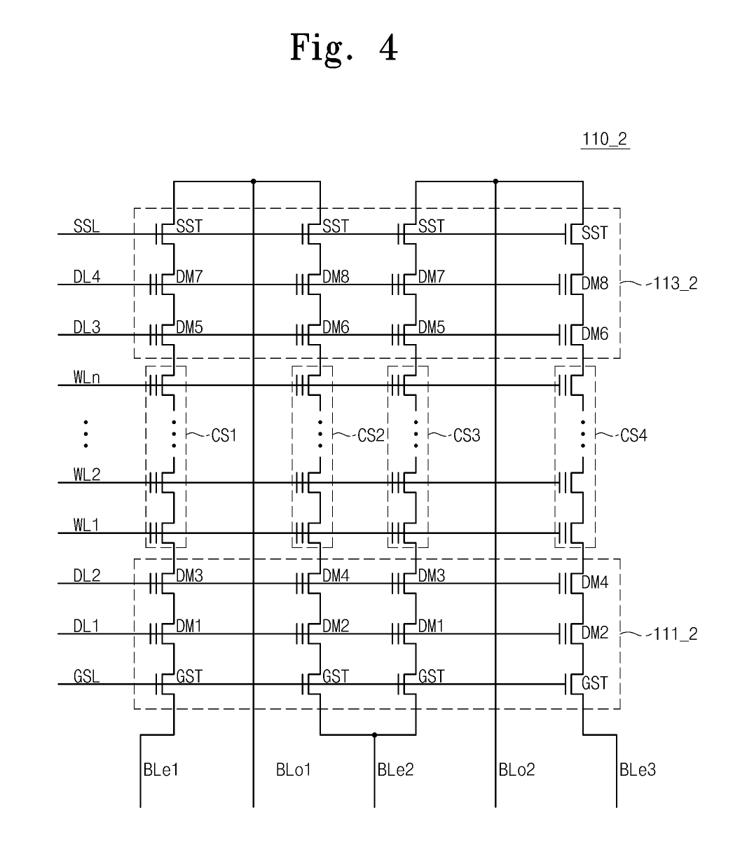

FIG. 4 is a circuit diagram showing another embodiment of memory cell array 110_1 of flash memory device 100 shown in FIG. 2. Referring to FIG. 4, a first switch 111_2 comprises ground selection transistors GST and dummy memory cells DM1˜DM4, and a second switch 113_2 comprises string selection transistors SST and dummy memory cells DM5˜DM8.

In the first switch 111_2, the dummy memory cells DM1 and DM3 are serially connected to the cell string CS1. The ground selection transistor GST is connected between the bit line BLe1 and the dummy memory cells DM1 and DM3. The dummy memory cells DM2 and DM4 are serially connected to the cell string CS2, and the ground selection transistor GST is connected between the bit line BLe2 and the dummy memory cells DM2 and DM4. The dummy memory cells DM1 and DM3 are serially connected to the cell string CS3, and the ground selection transistor GST is connected between the bit line BLe2 and the dummy memory cells DM1 and DM3. The dummy memory cells DM2 and DM4 are serially connected to the cell string CS4, and the ground selection transistor GST is connected between the bit line BLe3 and the dummy memory cells DM2 and DM4. While FIG. 4 shows one specific embodiment wherein the first switch 111_2 comprises two dummy cells connected each to the cell strings, the present invention is not restricted to this number of dummy memory cells or connection scheme. The number of the dummy memory cells connected each to the cell strings in the first switch 111_2 should be sufficient to enable selective connection of one of adjacent cell strings (e.g., CS2 and CS3) to a bit line (e.g., BLe2) through the first switch 111_2.

While in FIG. 4 the first switch 111_2 comprises the ground selection transistor GST connected between a corresponding bit line (e.g., BLe2) and the dummy memory cells (e.g., DM2 and DM4) of each cell string (e.g., CS2), the present invention is not restricted to this configuration. As stated ahead in conjunction with FIGS. 2 and 3, the flash memory device 100 according to the previously described embodiment of the present invention is able to apply bias voltages to the cell strings CS1˜CS4 by way of the bit lines BLe1˜BLe3 and the first switch 111_2 or by way of the bit lines BLo1 and BLo2 and the second switch 113_2. In other words, the transistor(s) forming the first switch 111_2 may optionally include the string selection transistor SST or the ground selection transistor GST. Otherwise, the transistor(s) forming the first switch 111_2 may be selection transistor(s).

The second switch 113_2 is interposed between the cell strings and the bit lines corresponding thereto, including the dummy memory cells DM5_DM8 and the string selection transistors SST.

In the second switch 113_2, the dummy memory cells DM5 and DM7 are serially connected to the cell string CS1, and the string selection transistor SST is connected between the bit line BLo1 and the dummy memory cells DM5 and DM7. The dummy memory cells DM6 and DM8 are serially connected to the cell string CS2, and the string selection transistor SST is connected between the bit line BLo1 and the dummy memory cells DM6 and DM8. The dummy memory cells DM5 and DM7 are serially connected to the cell string CS3, and the string selection transistor SST is connected between the bit line BLo2 and the dummy memory cells DM5 and DM7. The dummy memory cells DM6 and DM8 are serially connected to the cell string CS4, and the string selection transistor SST is connected between the bit line BLo3 and the dummy memory cells DM6 and DM8.

As in the foregoing example of the first switch 111_2, the dummy memory cells of the second switch 113_2 are not the limit of possible implementation components and connection schemes, whereby the second switch 113_2 includes only the string selection transistors SST.

With respect to an adjacent cell string CSn of the memory cell array 110_2 according to the embodiment of the invention illustrated in FIG. 4, one of the dummy memory cells coupled to a dummy word line DLn has a higher threshold voltage than ground voltage Vss, while the other has a lower threshold voltage than ground voltage Vss.

For example, the dummy memory cell DM1 of the dummy memory cells DM1 and DM2 which are connected to the dummy word line DL1 has a threshold voltage greater than ground voltage Vss, but the dummy memory cell DM2 has a threshold voltage less than ground voltage Vss. To the contrary, the dummy memory cell DM1 may have a lower threshold voltage than ground voltage Vss, while the dummy memory cell DM2 may have a higher threshold voltage than ground voltage Vss.

In the first switch 111_2 of the memory cell array 110_2 according to the embodiment of the invention illustrated in FIG. 4, one of the dummy memory cells coupled to a cell string CSn has a higher threshold voltage than ground voltage Vss, while the other has a lower threshold voltage than ground voltage Vss.

For instance, in the first switch 111_2, the dummy memory cell DM1 of the dummy memory cells DM1 and DM3 which are serially connected to the cell string CS1 has a threshold voltage greater than ground voltage Vss, but the dummy memory cell DM3 has a threshold voltage less than ground voltage Vss. To the contrary, the dummy memory cell DM1 may have a lower threshold voltage than ground voltage Vss, while the dummy memory cell DM3 may have a higher threshold voltage than ground voltage Vss.

For clarity and simplicity of description, it is assumed that the dummy memory cells DM1, DM4, DM5, and DM8 have lower threshold voltages than ground voltage Vss while the dummy memory cells DM2, DM3, DM6, and DM7 have higher threshold voltages than ground voltage Vss.

Under such assumptions, it can be seen that the dummy memory cells DM1˜DM8 operate in the same mode with the transistors T1˜T8 of the memory cell array 110_1 shown in FIG. 2. For instance, the dummy memory cell DM1 operates in the same manner with the transistor T1 and the dummy memory cell DM2 operates in the same manner with the transistor T2. Also, the other dummy memory cells DM3˜DM8 operate in the same manner with the transistors T3˜T8.

Therefore, the dummy memory cells DM1, DM4, DM5, and DM8 are normally turned ON like the transistors T1, T4, T5, and T8. The dummy memory cells DM2, DM3, DM6, and DM7 selectively connect the cell strings CS1˜CS4 to the bit lines BLe1˜BLe3 and BLo1 and BLo2, as like the transistors T2, T3, T6, and T7.

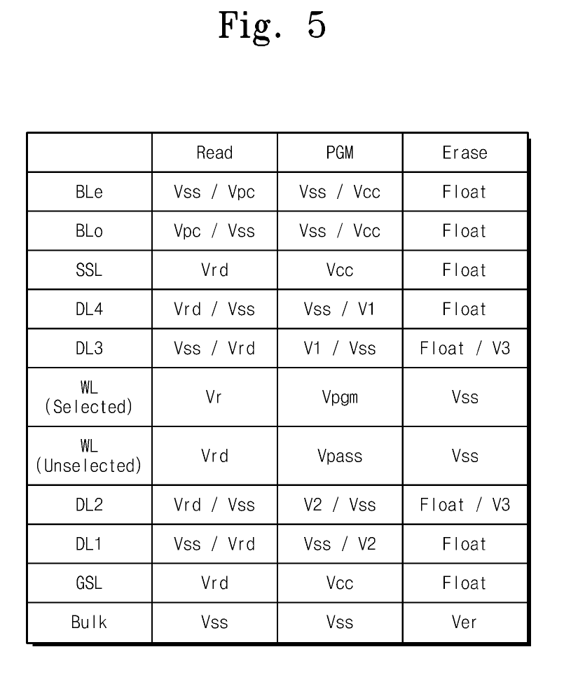

FIG. 5 is a table listing the voltage bias conditions for operations executed by the memory cell array 110_2 of FIG. 4. The table of FIG. 5 summarizes voltage conditions for read, programming, and erase operations to the memory cell array 110_2 of FIG. 4. The voltage conditions shown in FIG. 5 are generally the same as those shown in FIG. 3, except the voltages for the string and ground selection lines, SSL and GSL, have been added, and voltages of the dummy word lines, DL2 and DL3, have been modified for the erase operation. The string and ground selection transistors SST and GST are turned ON during read and programming operations, but turned OFF during the erase operation. The read and programming operations executed by the memory cell array 110_2 may be performed in a manner otherwise similar to the embodiments described with reference to FIGS. 2 and 3.

During the programming operation, the cell strings CS1˜CS4 are simultaneously programmed by providing bias voltages to the cell strings CS1˜CS4 by way of the bit lines, BLe1˜BLe3 and BLo1 and BLo2, connected to both ends of the cell strings CS1˜CS4. The read operation may be executed alternately to even and odd cell strings among the cell strings CS1˜CS4, thereby preventing a read fail due to capacitive couplings.

During the erase operation, the dummy word lines DL2 and DL3 are floated or supplied with a voltage V3. While the dummy word lines DL2 and DL3 are floated, control gate voltages of the dummy memory cells DM1˜DM8 rise to the level of the erase voltage Ver due to coupling effects, if the erase voltage Ver is applied to the semiconductor bulk BULK. Thus, it prevents the dummy memory cells DM1˜DM8 from being erased. Ground voltage Vss is applied to the word lines WL1˜WLn, so the memory cells (MC) are erased by F-N tunneling.

Under these conditions, the control gates of the dummy memory cells DM5 and DM6 are set to the erase voltage Ver, and the control gates of the memory cells coupled to the word line WLn are set to ground voltage Vss. Generally, the erase voltage Ver is a higher voltage generated by a conventional charge pump circuit. Thus, an electric field is strongly formed between the memory cells coupled to the word line WLn and the dummy memory cells DM5 and DM6. During the erase operation, charge leaking from the memory cells coupled to the word line WLn may accumulate in the dummy memory cells DM5 and DM6 under the influence of the electric field. In other words, the dummy memory cells DM5 and DM6 may be softly programmed during an erase operation. This soft-programming problem may occur even between the memory cells couple to the word line WL1 and the dummy memory cells DM3 and DM4.

To resolve the soft-programming problem, the voltage V3 is applied to the dummy word lines DL2 and DL3. The voltage V3 has a level between ground voltage Vss and the erase voltage Ver. The voltage V3 is set to generate an electric field less strong than the electric field causing charge from the word lines WL1 and WLn to accumulate on the charge storage layers of the dummy memory cells DM3, DM4, DM5, and DM6. Additionally, the voltage V3 is set to prevent the dummy memory cells DM3, DM4, DM5, and DM6 from being erased. For example, if ground voltage Vss is 0V and the erase voltage Ver is 20V, the voltage V3 may be set at about 10V.

The programming and erase operations executed in relation to the memory cell array 110_2 according to the embodiment of FIG. 4 are generally performed in a manner similar to the operations described above with reference to FIGS. 2 and 3.

The threshold voltage of a memory cell (or memory cell transistor) may be changed as charge accumulates on its charge storage layer. If positive charge is greater than negative charge in the charge storage layer, an electric field will formed between a constituent channel region and the charge storage layer. Owing to this electric field, a depletion layer is generated in the channel region and free electrons flow into the depletion layer from surrounding source/drain regions. Thus, even when ground voltage Vss is applied to the control gate of the memory cell, the memory cell is turned ON by formation of this conductive channel. That is, the memory cell finally has a negative threshold voltage.

The depletion transistor is formed by doping n-type impurities into a p-well for n-type source/drain regions and doping n-type impurities into a channel region between the n-type source/drain regions. The depletion transistor has a negative threshold voltage by the n-type impurities doped into the channel region. As the source/drain regions are doped with n-type impurities, an amount of negative charges in the source/drain regions of the depletion transistor is larger than that of the memory cell transistor.

Referring now to FIGS. 2 and 4, the dummy memory cells DM1, DM4, DM5, and DM8 which have negative threshold voltages, and the depletion transistors T1, T4, T5, and T8, are connected between the cell strings CS1˜CS4 and the bit lines BLe1˜BLe3 and BLo1 and BLo2, respectively. If the same bias voltages are applied thereto, an amount of charges leaking through the depletion transistors T1, T4, T5, and T8 is larger than that through the dummy memory cells DM1, DM4, DM5, and DM8 which have negative threshold voltages.

Therefore, by configuring the first and second switches 111_2 and 113_2 with the dummy memory cells DM1, DM4, DM5, and DM8 instead of the depletion transistors T1, T4, T5, and T8 shown in FIG. 2, the switches reduce an amount of charge leakage through the first and second switches 111_2 and 113_2. As a result, the memory cell array 110_2 according to the embodiment illustrated in FIG. 4 is useful in preventing or reducing charge leakage from the cell strings CS1˜CS4 toward the bit lines, BLe1˜BLe3 and BLo1 and BLo2 during a programming operation.

As aforementioned, the first and second switches 111_2 and 113_2 implemented with dummy memory cells DM1, DM4, DM5, and DM8 are advantageous to reducing charge leakage from the cell strings CS1˜CS4. And the dummy memory cells DM2, DM3, DM6, and DM7, having positive threshold voltages, also contribute to a reduction in charge leakage from the cell strings CS1˜CS4. Further, according to the illustrated embodiment of FIG. 4, the memory cell array is able to scale down the size of the selection transistors SST and GST of the switches 111_2 and 113_2 without increasing charge leakage.

A general process for fabricating a flash memory device in accordance with the invention will be described. Those skilled in the art are familiar with the specific range and class of processes capable of accomplishing each fabrication step.

First a tunnel insulation film is formed on a substrate. On the tunnel insulation film is formed a charge storage layer. On the charge storage layer is formed a blocking insulation film. Then, a conductive layer is formed on the resultant structure, which is used for gates, control gates, word lines, dummy word lines, and selection lines. On the conductive layer is laid a photoresist film. The photoresist film is shaped to a photoresist pattern for defining the word lines, the dummy word lines, and the selection lines. Afterward, the conductive layer is patterned by the photoresist pattern, forming the word lines, the dummy word lines, and the selection lines.

If the various conductive lines have different widths, pattern defects associated with the lines may be generated due to differences of pattern densities. For instance, selection lines may be wider than the word lines or the dummy word lines. For that reason, a pattern defect may arise in relation to at least one of the word lines or the dummy word lines adjacent to the selection lines. In other words, the word line or the dummy word line adjacent to the selection line may be enlarged or reduced in width.

As aforementioned, the memory cell array of the embodiment illustrated in FIG. 4 may be configured with reduced line widths for the selection lines. Thus, the potentially negative effects of adjacent, disparate-width lines may be mitigated for adjacent memory cells (MC) or dummy memory cells (DMC) in relation to the patterns of selection lines SSL and GSL. This effect prevents or reduces the occurrence of pattern defects in word lines or dummy word lines. Moreover, as the string and ground selection lines SSL and GSL can be smaller in width, the memory cell array 110_2 enjoys improved integration density.

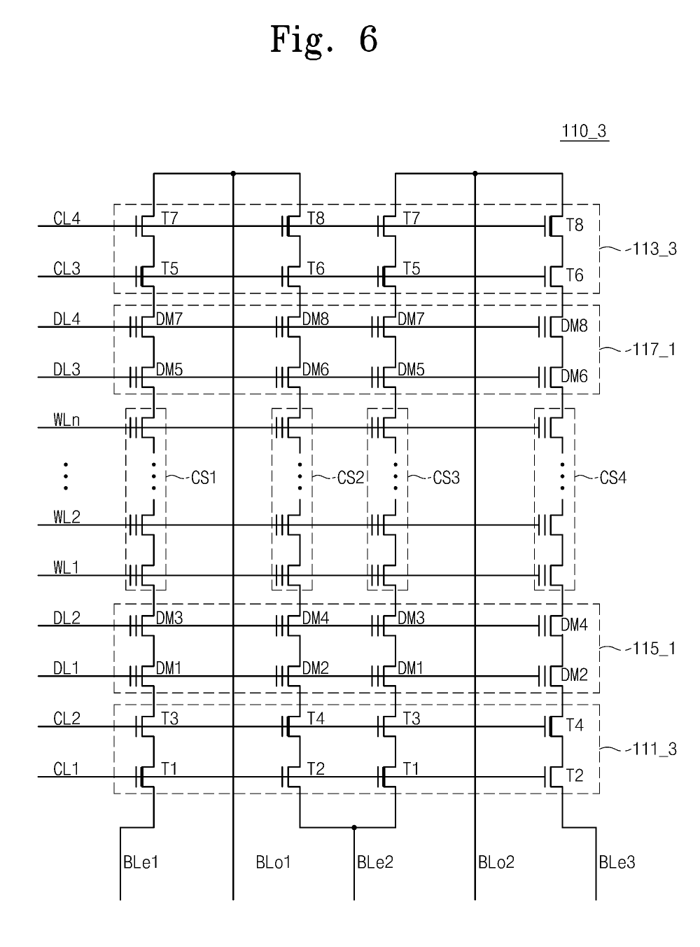

FIG. 6 is a circuit diagram showing yet another embodiment for a memory cell array of the flash memory device 100 shown in FIG. 2. Referring to FIG. 6, a first switch 111_3 comprises the transistors T2 and T3, and the depletion transistors T1 and T4 just like the first switch 111_1 shown in FIG. 2. A first switch 113_3 comprises the transistors T6 and T7, and the depletion transistors T5 and T8 just like the second switch 113_1 shown in FIG. 2.

A first dummy cell array 115_1 comprises the dummy memory cells DM1˜DM4 just like the first switch 111_2 shown in FIG. 4. A second dummy cell array 117_1 comprises the dummy memory cells DM5˜DM8 just like the second switch 113_2 shown in FIG. 4.

With respect to an adjacent cell string CSn of the memory cell array 110_3 according to the embodiment illustrated in FIG. 6, one of the dummy memory cells coupled to a dummy word line DLn has a higher threshold voltage than ground voltage Vss, while the other has a lower threshold voltage than ground voltage Vss.

For example, the dummy memory cell DM1 of the dummy memory cells DM1 and DM2 which are connected to the dummy word line DL1 has a threshold voltage greater than ground voltage Vss, but the dummy memory cell DM2 has a threshold voltage less than ground voltage Vss. To the contrary, the dummy memory cell DM1 may have a lower threshold voltage than ground voltage Vss, while the dummy memory cell DM2 may have a higher threshold voltage than ground voltage Vss.

In the dummy cell arrays 115_1 and 117_1 of the memory cell array 110_3 according to the embodiment illustrated in FIG. 6, one of the dummy memory cells coupled to a cell string CSn has a higher threshold voltage than ground voltage Vss, while the other has a lower threshold voltage than ground voltage Vss.

For instance, in the first dummy cell array 115_1, the dummy memory cell DM1 of the dummy memory cells DM1 and DM3 which are serially connected to the cell string CS1 has a threshold voltage greater than ground voltage Vss, but the dummy memory cell DM3 has a threshold voltage less than ground voltage Vss. To the contrary, the dummy memory cell DM1 may have a lower threshold voltage than ground voltage Vss, while the dummy memory cell DM3 may have a higher threshold voltage than ground voltage Vss.

For clarity and simplicity of description, it is assumed that the dummy memory cells DM1, DM4, DM5, and DM8 have lower threshold voltages than ground voltage Vss while the dummy memory cells DM2, DM3, DM6, and DM7 have higher threshold voltages than ground voltage Vss. In other words, the dummy cell arrays 115_1 and 117_1 operate in a manner similar to that of the first and second switches 111_3 and 113_3 described in conjunction with FIGS. 4 and 5.

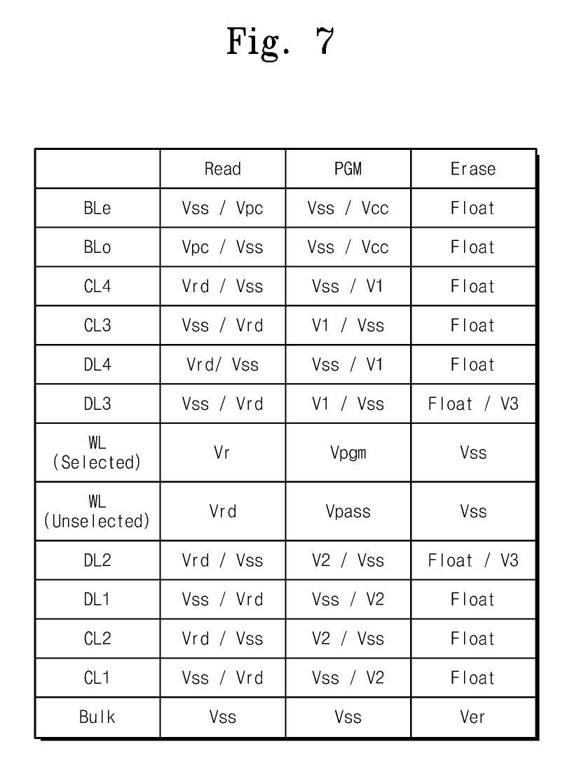

FIG. 7 is another table listing voltage bias conditions for operations executed in relation to the memory cell array 110_3 shown in FIG. 6. As may be seen from FIG. 7, voltage conditions for the control lines CL1˜CL4 are the same as those aforementioned in conjunction with FIGS. 2 and 3, and voltage conditions for the dummy word lines DL1˜DL4 are same as those aforementioned in conjunction with FIGS. 4 and 5. That is, in the memory cell array 110_3 shown in FIG. 6, the read, programming, and erase operations are performed in a manner similar to those aforementioned in conjunction with FIGS. 2 through 5.

During the programming operation, the cell strings CS1˜CS4 are simultaneously programmed by providing bias voltages to the cell strings CS1˜CS4 via the bit lines, BLe1˜BLe3 and BLo1 and BLo2, connected to both ends of the cell strings CS1˜CS4. Again, the read operation may be performed alternately to the even and odd cell strings among the cell strings CS1˜CS4, thereby preventing a read failure due to capacitive couplings.

During the erase operation, the dummy word lines DL2 and DL3 are supplied with a voltage V3. By disposing the dummy cell arrays 115_1 and 117_1 between the first and second switches 111_3 and 113_3 and the cell strings CS1˜CS4, the possibility of pattern defects related to the word lines or the dummy word lines may reduced and the integration density of the memory cell array 110_3 may be improved.

The memory cell array 110_3 according to the embodiment illustrated in FIG. 6 comprises the dummy cell arrays 115_1 and 117_1 and the switches 111_3 and 113_3. The dummy cell arrays 115_1 and 117_1 may be programmed to a target threshold voltage by interposing the switches 111_3 and 113_3 between the dummy cell arrays 115_1 and 117_1 and the bit lines BLe1˜BLe3 and BLo1 and BLo2. A method for programming the dummy cell arrays 115_1 and 117_1 may be performed similar to the aforementioned with reference to FIGS. 2 and 3 by controlling the first and second switches 111_3 and 113_3 to selectively connect the cell strings CS1˜CS4 electrically with the bit lines BLe1˜BLe3 and BLo1 and BLo2, and biasing the bit lines BLe1˜BLe3 and BLo1 and BLo2.

The memory cell array 110_3 according to the embodiment illustrated in FIG. 6 is configured to enable a programming operation to the dummy cell arrays 115_1 and 117_1. Thus, it may be understood that there is operative improvement of the dummy cell arrays 115_1 and 117_1 connecting the cell strings CS1˜CS4, electrically and selectively, to the bit lines BLe1˜BLe3 and BLo1 and BLo2.

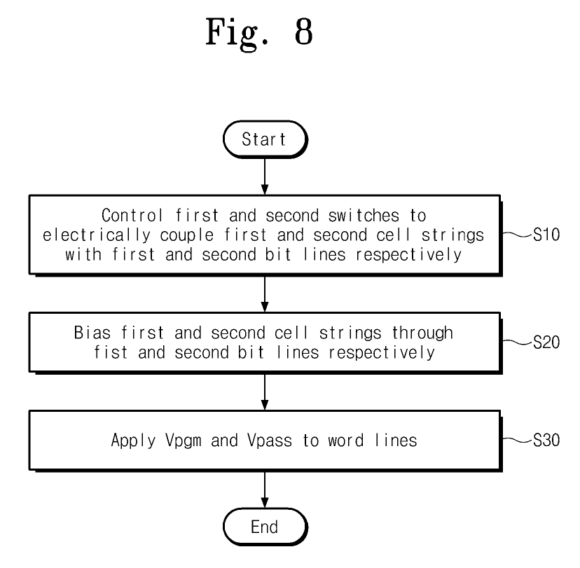

FIG. 8 is a flow chart summarizing a programming method for the various flash memory devices 100 of FIGS. 2 through 7 in accordance with embodiments of the present invention. Referring collectively to FIGS. 2 through 8, the control logic circuit 150 enables the first and second switches, 111_1˜111_3 and 113_1˜113_3, to couple the first and second cell strings (e.g., CS2 and CS3) with the first and second bit lines (e.g., BLe2 and BLo2) (S10).

During step, as the dummy cell arrays 115_1 and 117_1 shown in FIG. 6 are operating in the same manner as the first and second switches 111_1˜111_3 and 113_1˜113_3, the first and second cell strings CS1 and CS3 are electrically connected each to the bit lines BLe2 and BLo2 corresponding thereto.

Then, the control logic circuit 150 controls the page buffer circuit 120 to bias the first and second cell strings CS2 and VS3 respectively through the first and second bit lines BLe2 and BLo2 (S20). For example, if the cell strings CS2 and CS3 are to be programmed, the page buffer circuit 120 biases the cell strings on the ground voltage Vss. If the cell strings CS2 and CS3 are to be program-inhibited, the page buffer circuit 120 biases the cell strings on the program-inhibition voltage (e.g., Vcc).

Next, the control logic circuit 150 applies the program voltage Vpgm to a selected word line, by way of the row decoder 140, and applies the pass voltage to unselected word lines (S30). The flash memory device 100 according to embodiments of the invention is operable in a coincidental programming operation with the first and second cell strings CS2 and CS3. In other words, it is possible for the flash memory device 100 to program two or more cell strings (e.g., CS1˜CS4) sharing a bit line simultaneously.

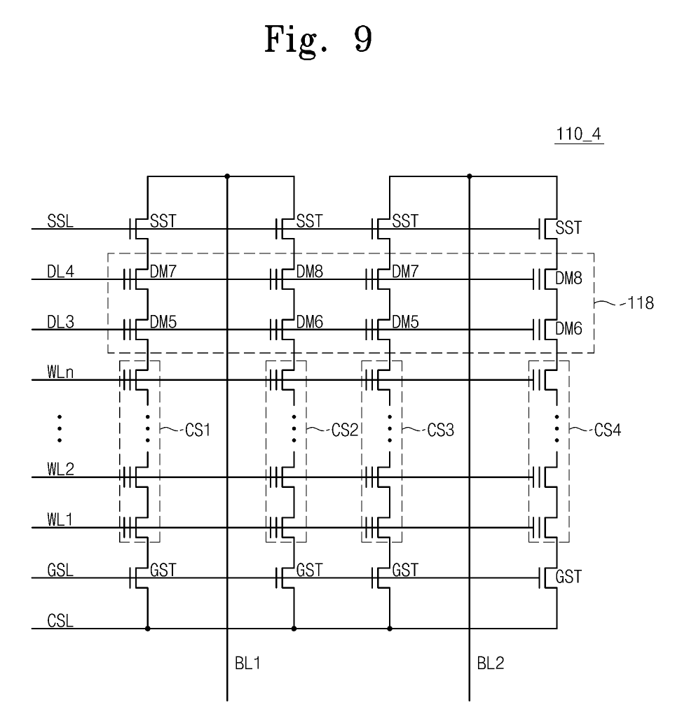

FIG. 9 is a circuit diagram illustrating yet another embodiment of the memory cell array of the flash memory device 100 shown in FIG. 2. Referring to FIG. 9, the ground selection transistors GST are interposed between the cell strings CS1˜CS4 between a common source line CSL. The cell strings CS1˜CS4 are electrically connected to bit lines BL1 and BL2 corresponding thereto through a switch 118. For instance, through the switch 118, the cell strings CS1 and CS2 are electrically connected to the bit line BL1 while the cell strings CS3 and CS4 are electrically connected to the bit line BL2.

The switch 118 includes the dummy memory cells DM5˜DM8. One of the dummy memory cells coupled to a dummy word line DLn has a higher threshold voltage than ground voltage Vss, while the other has a lower threshold voltage than ground voltage Vss. For example, the dummy memory cell DM5 of the dummy memory cells DM5 and DM6 which are connected to the dummy word line DL3 has a threshold voltage greater than ground voltage Vss, but the dummy memory cell DM6 has a threshold voltage less than ground voltage Vss. To the contrary, the dummy memory cell DM5 may have a lower threshold voltage than ground voltage Vss, while the dummy memory cell DM6 may have a higher threshold voltage than ground voltage Vss.

In the switch 118, one of the dummy memory cells coupled to a cell string CSn has a higher threshold voltage than ground voltage Vss, while the other has a lower threshold voltage than ground voltage Vss.

For instance, in the first switch 118, the dummy memory cell DM5 of the dummy memory cells DM5 and DM7 which are serially connected to the cell string CS1 has a threshold voltage greater than ground voltage Vss, but the dummy memory cell DM7 has a threshold voltage less than ground voltage Vss. To the contrary, the dummy memory cell DM5 may have a lower threshold voltage than ground voltage Vss, while the dummy memory cell DM7 may have a higher threshold voltage than ground voltage Vss.

For clarity and simplicity of description, it is now assumed that the dummy memory cells DM5 and DM8 have lower threshold voltages than ground voltage Vss while the dummy memory cells DM6 and DM7 have higher threshold voltages than ground voltage Vss. The switch 118, thus, operates in a manner similar to the second switches 113_1˜113_3 aforementioned in conjunction with FIGS. 2 through 8.

In FIG. 9, the cell strings CS1 and CS2 are alternately connected to the bit line BL1 in accordance with voltage levels of the dummy word lines DL3 and DL4. The cell strings CS3 and CS4 are alternately connected to the bit line BL2 in accordance with voltage levels of the dummy word lines DL3 and DL4. Thus, read and programming operations may be performed alternately to the two cell strings CS1 and CS3, or CS2 and CS4.

In the memory cell array 110_4, the switch 118 comprises the dummy memory cells DM5˜DM8. Thus, as aforementioned, the selection transistor SST may be implemented with a smaller size. As a result, the possibility of pattern defects arising in the memory cell array 110_4 is reduced while integration density is enhanced.

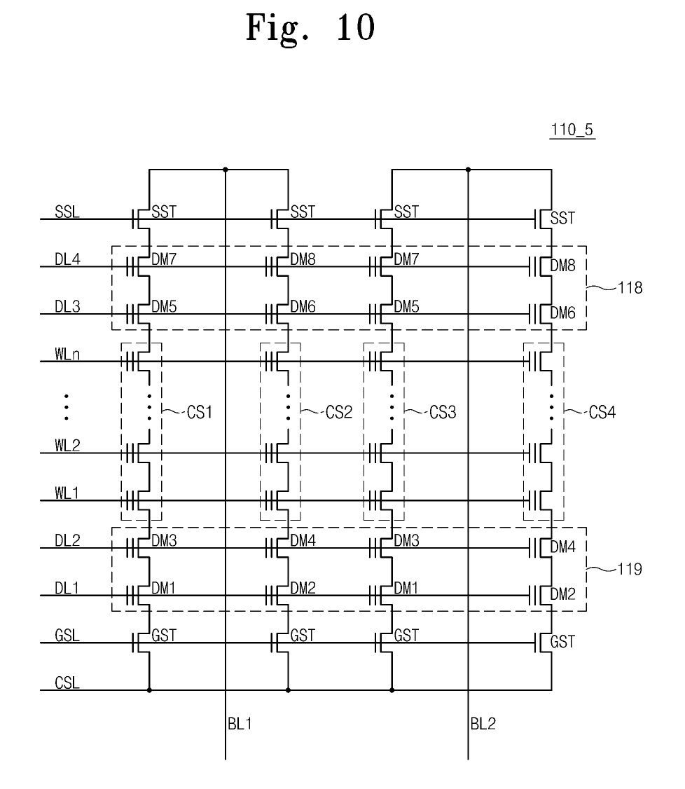

FIG. 10 is a circuit diagram illustrating yet another embodiment of the memory cell array of the flash memory device 100 shown in FIG. 2. The memory cell array 110_5 shown in FIG. 10 is formed by adding a switch 119 to the memory cell array 110_4 shown in FIG. 9. The switch 119 includes the dummy memory cells DM1˜DM4.

One of the dummy memory cells coupled to a dummy word line DLn has a higher threshold voltage than ground voltage Vss, while the other has a lower threshold voltage than ground voltage Vss. For example, the dummy memory cell DM1 of the dummy memory cells DM1 and DM2 which are connected to the dummy word line DL1 has a threshold voltage greater than ground voltage Vss, but the dummy memory cell DM2 has a threshold voltage less than ground voltage Vss. To the contrary, the dummy memory cell DM1 may have a lower threshold voltage than ground voltage Vss, while the dummy memory cell DM2 may have a higher threshold voltage than ground voltage Vss.

In the switch 119, one of the dummy memory cells serially coupled to a cell string CSn has a higher threshold voltage than ground voltage Vss, while the other has a lower threshold voltage than ground voltage Vss.

For instance, in the switch 119, the dummy memory cell DM1 of the dummy memory cells DM1 and DM3 which are serially connected to the cell string CS1 has a threshold voltage greater than ground voltage Vss, but the dummy memory cell DM3 has a threshold voltage less than ground voltage Vss. To the contrary, the dummy memory cell DM1 may have a lower threshold voltage than ground voltage Vss, while the dummy memory cell DM3 may have a higher threshold voltage than ground voltage Vss.

For clarity and simplicity of description, it will now be assumed that the dummy memory cells DM1 and DM3 have lower threshold voltages than ground voltage Vss while the dummy memory cells DM2 and DM4 have higher threshold voltages than ground voltage Vss. The switch 119 thus operates in a manner similar to that of the second switches 111_1˜111_3 aforementioned in conjunction with FIGS. 2 through 8.

However in FIG. 10, the cell strings CS1 and CS2 are alternately connected to the bit line BL1 in accordance with voltage levels of the dummy word lines DL1 and DL2. The cell strings CS3 and CS4 are alternately connected to the bit line BL2 in accordance with voltage levels of the dummy word lines DL1 and DL2. Thus, read and programming operations may be performed alternately to the two cell strings CS1 and CS3, or CS2 and CS4.

In the memory cell array 110_5, the switch 119 comprises the dummy memory cells DM1˜DM8. Thus, as aforementioned, the selection transistors SST and GST may be implemented with a smaller size. As a result, the possibility of pattern defects for lines associated with the memory cell array 110_5 may be reduced and integration density may be improved.

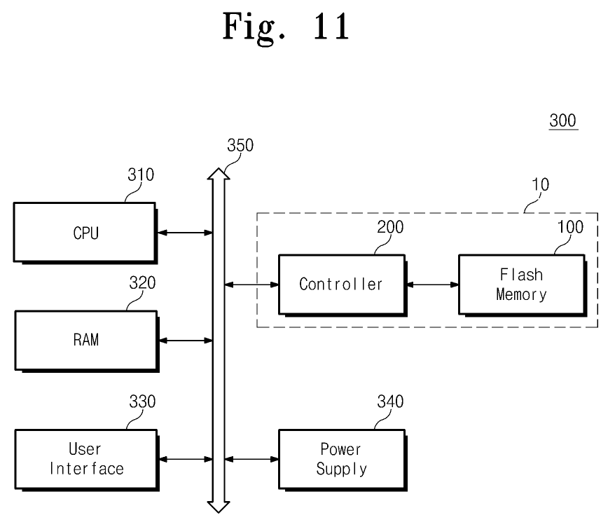

FIG. 11 is a general block diagram of a computing system 300 including the memory system 10 shown in FIG. 1. Referring to FIG. 11, the computing system 300 comprises a central processing unit (CPU) 310, a RAM 320, a user interface 330, a power supply 340, and the memory system 10.

The memory system 10 is electrically connected to the CPU 310, the RAM 320, the user interface 330, and the power supply 340 by way of a system bus 350. Data provided through the user interface 330 or processed by the CPU 310 are stored in the memory system 10. The memory system 10 is comprised of the flash memory device 100 and the controller 200.

If the memory system 10 is employed as a solid state disk (SSD) in the computing system 300, it is able to improve an operation rate of the computing system 300. Although not shown in FIG. 11, the computing system 300 may be further equipped with an application chipset, a camera image processor, and so forth.

The above-disclosed subject matter is to be considered illustrative, and not restrictive, and the appended claims are intended to cover all such modifications, invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A flash memory device comprising:
a first switch configured to selectively connect one of a first cell string and a second cell string to a first bit line;
a second switch configured to connect the second cell string to a second bit line; and
a control logic circuit configured to respectively provide bias voltages to the first and second cell strings through the first and second bit lines to enable simultaneously programming of the first and second cell stings.

2. The device of claim 1, wherein the control logic circuit is further configured to control execution of a read operation alternately to the first and second cell strings.

3. The device of claim 1, wherein the first switch comprises:
at least two dummy memory cells connected to the first cell string;
at least two dummy memory cells connected to the second cell string; and
selection transistors interposed between the dummy memory cells of the first cell string and the first bit line, and between the dummy memory cells of the second cell string and the first bit line.

4. The device of claim 3, wherein one of dummy memory cells coupled to a dummy word line has a threshold voltage greater than a ground voltage while the other has a threshold voltage less than the ground voltage.

5. The device of claim 3, wherein during an erase operation, the control logic circuit is further configured to apply a predetermined voltage to dummy memory cells adjacent to the first and second cell strings.

6. The device of claim 1, further comprising:
at least two dummy memory cells interposed between the first cell string and the first switch; and
at least two dummy memory cells interposed between the second cell string and the first switch.

7. The device of claim 6, wherein one of dummy memory cells coupled to a dummy word line has a threshold voltage greater than a ground voltage while the other has a threshold voltage less than the ground voltage.

8. The device of claim 6, wherein the control logic circuit is further configured to connect one of the first and second cell strings to the first bit line through the dummy memory cells and the first switch.

9. The device of claim 6, wherein during an erase operation, the control logic circuit is further configured to apply a predetermined voltage to dummy memory cells adjacent to the first and second cell strings.

10. The device of claim 6, wherein the second switch is further configured to selectively connect one of the second cell string and a third cell string to the second bit line, and comprises;
at least two dummy memory cells interposed between the second cell string and the second switch; and
at least two dummy memory cells interposed between the third cell string and the second switch.

11. The device of claim 10, wherein one of dummy memory cells coupled to a dummy word line has a threshold voltage greater than a ground voltage while the other has a threshold voltage less than the ground voltage.

12. The device of claim 11, wherein the control logic circuit is further configured to selectively connect one of the second and third cell strings to the second bit line through the dummy memory cells and the second switch.

13. A flash memory device comprising:
a plurality of cell strings connected between first and second switches;
first bit lines connected to one of the 2n'th and 2n−1'th cell strings, where “n” is a positive integer among the plurality of cell strings through the first switch;
second bit lines connected to one of the 2n'th and 2n+1'th cell strings among the plurality of cell strings through the second switch; and
a control logic circuit configured to selectively connected the 2n'th and 2n−1'th cell strings to one of the first bit lines or one of the second bit lines, such that plurality of cell strings are simultaneously programmed by providing bias voltages through the first and second bit lines.

14. The device of claim 13, wherein the control logic circuit is further configured to control a read operation conducted alternately to the 2n'th and 2n+1'th cell strings.

15. The device of claim 13, further comprising:
at least two dummy memory cells interposed between the 2n'th cell string and the first switch; and
at least two dummy memory cells interposed between the 2n−1'th cell string and the first switch.

16. The device of claim 15, further comprising:
at least two dummy memory cells interposed between the 2n'th cell string and the second switch; and
at least two dummy memory cells interposed between the 2n+1'th cell string and the second switch.

17. The device of claim 16, wherein among dummy memory cells coupled to a dummy word line, a dummy memory cell coupled to the 2n'th memory cell string has a threshold voltage greater than a ground voltage, while a dummy memory cell coupled to the 2n+1'th memory cell string has a threshold voltage less than the ground voltage.

18. A memory system comprising:
a flash memory device; and
a controller configured to control the flash memory device,
wherein the flash memory device comprises:
a first switch connecting a first cell string to a first bit line;
a second switch connecting a second cell string to a second bit line; and
a control logic circuit respectively providing bias voltages to the first and second cell strings through the first and second bit lines, and controlling the first and second cell stings to be programmed simultaneously.

19. The system of claim 18, wherein the flash memory device and the controller are integrated into a single integrated circuit chip.

20. The device of claim 18, wherein the flash memory device and the controller form a solid state disk.
